(19) United States
(12) Patent Application Publication
(10) Pub. No.: US 2012/0248950 A1
(43) Pub. Date: Oct. 4, 2012

(54) HERMETICALLY SEALED CONTAINER, IMAGE DISPLAY APPARATUS, AND THEIR MANUFACTURING METHODS

(75) Inventor: Kenji Niibori, Hiratsuka-shi (JP)

(73) Assignee: CANON KABUSHIKI KAISHA, Tokyo (JP)

(21) Appl. No.: 13/403,190

(22) Filed: Feb. 23, 2012

(30) Foreign Application Priority Data
Mar. 30, 2011 (JP) 2011-073901

(51) Int. Cl. H05K 5/02; H05K 13/00

(52) U.S. Cl. 312/223.1; 156/281

(57) ABSTRACT

A hermetic container comprises first and second substrates and bonded by bonding members to form a hermetically sealed space therebetween. Second bonding members placed on both sides of a first bonding member to form the hermetically sealed space between the substrates are sandwiched between the substrates, thereby bonding the substrates together with the first bonding member. A height of first bonding member is higher than that of second bonding member and at least one of the substrates is elastically deformed and is bonded by the first bonding member and the second bonding members. Thus, the hermetic container in which a compressing force has been applied to a height direction of the first bonding member is obtained.

### BACKGROUND OF THE INVENTION

1. Field of the Invention

The present invention relates to a hermetically sealed container (hereinbelow, referred to as a hermetic container) in which a first substrate and a second substrate which are placed in opposition to each other to firm a gap therebetween are bonded by a bonding member which is sandwiched between both of those substrates, is placed so as to surround the gap, and forms a hermetically sealed space inside of the substrates, and also relates to an image display apparatus using the hermetic container as an envelope and to manufacturing methods of the hermetic container and the image display apparatus.

2. Description of the Related Art

In the related art, image display apparatuses of a flat panel type such as organic LED display (OLED), field emission display (FED), plasma display panel (PDP), and the like have been known. Each of those image display apparatuses has an envelope which is manufactured by hermetically bonding two substrates such as glass plates or the like placed in opposition to each other and whose internal space is partitioned from an external space. In order to manufacture the hermetic container such as an envelope or the like of the flat panel type image display apparatus, a gap specifying member and a second local bonding member to bond the gap specifying member are placed between the substrates placed in opposition to each other in accordance with the necessity, a frame-shaped second continuous bonding member is placed in a peripheral portion, and heat bonding is performed. As a heating method of the second bonding member, a method of baking the whole substrates by a heating furnace or a method of selectively heating the periphery of the second bonding member by the local heating has been known. The local heating is more advantageous than the whole heating from viewpoints of a heating/cooling time, an energy which is required to heat, a productivity, a prevention of a heat deformation of the container, a prevention of a heat deterioration of a functional device placed in the container, and the like. Particularly, a laser beam has been known as a local heating unit. It has also been known that the manufacturing method of the hermetic container by the local heating unit can be applied as a manufacturing method of vacuum heat insulation glass having no functional devices therein.

A sealing structure of the organic LED display (OLED) has been disclosed in the description of U.S. Patent Publication No. 2009/0009063. That is, as a sealing structure of the OLED, there has been disclosed such a structure that between first and second substrates, glass frit is placed as double loop patterns surrounding an organic light emitting device portion and the first and second substrates are bonded by the double loop patterns, thereby increasing a sealing force as compared with that in the case of a single loop pattern. As a sealing structure of the OLED, in the description of U.S. Patent Publication No. 2008/0143247, there has also been disclosed such a structure that glass frit is placed between first and second substrates so as to surround an organic light emitting device portion and an adhesive is placed outside of the glass frit, thereby reinforcing a bonding strength between the two substrates.

On the other hand, in many cases, a temperature change of the hermetic container does not uniformly occur as a whole. In Patent Literature 1, even if coefficients of thermal expansion of the inner and outer glass frit are equal, for example, if a temperature difference occurred between the inner and outer glass frit, a difference occurs between expanding degrees or contracting degrees of the inner and outer glass frit. A tractive force in a height direction acts on the glass frit which was lowered by the difference between the expanding degrees or the contracting degrees. If the temperature difference occurred in a length direction of one or both of the inner and outer glass frit, a height difference occurs in the length direction of the relevant glass frit and a tractive force in the height direction acts on the lower portion. On the other hand, generally, coefficients of thermal expansion of glass frit and an adhesive in Patent Literature 2 differ. However, even in such a case, if the adhesive was expanded larger than the glass frit or the glass frit was contracted larger than the adhesive, a tractive force in the height direction acts on the glass frit. If the temperature difference occurred in the length direction of the glass frit, a height difference occurs in the length direction of the glass frit and the tractive force in the height direction acts on the lower portion.

The glass frit is a brittle material and a strength to the tractive force is extremely smaller than a strength to the compressing force. Therefore, if the tractive force in the height direction acts on the glass frit as mentioned above, the glass frit is damaged and hermetic sealing is liable to be lost. In the case of the sealing structure of the foregoing Patent Literature 1, the double glass frit is provided. In the case of the sealing structure of the foregoing Patent Literature 2, both of the glass frit and the adhesive are used. Therefore, in both of those cases, a bonding strength between the two substrates is improved to a certain extent. There is, however, such a problem that a reliability about the hermetic sealing is not sufficient due to the reasons mentioned above. For example, if the hermetic sealing of the hermetic container constructing the envelope of the OLED is lost, such a problem that an external atmosphere enters the organic light emitting device portion and causes an organic light emitting device to be deteriorated occurs.

The invention solves the foregoing problems and with respect to a hermetic container in which first and second substrates are bonded by bonding members adapted to form a hermetically sealing space between both of the substrates, it is an object of the invention to obtain high bonding strength and hermetic sealing even in the case where the bonding members are formed from a brittle material such as glass frit. It is another object of the invention to improve a reliability of an image display apparatus using the hermetic container as an envelope and to provide such a hermetic container and an easy manufacturing method of an image display apparatus using such a hermetic container as an envelope.

### SUMMARY OF THE INVENTION

According to a first aspect of the present invention, a hermetic container comprises: first and second substrates placed in opposition to each other to firm a gap between the first and second substrates; a first annular bonding member placed to enclose the gap, and bonded to the first and second substrates, so as to form a hermetically sealed space surrounded with the first annular bonding member and the first and second substrates; and a second bonding member placed, between the first and second substrates, in a region different from a region in which the first annular bonding member is placed, and bonded to the first and second substrates, wherein the second bonding member has a height smaller than a height of the first annular bonding member, at least one of the first and second substrates is elastically deformed, from a region bonded to the first bonding member to a region bonded to the second bonding member, so as to form a compressing force in a direction of the height of the first bonding member.

According to a second aspect of the present invention, a method for manufacturing a hermetic container, wherein the hermetic container comprises: first and second substrates placed in opposition to each other to firm a gap between the first and second substrates; a first annular bonding member placed to enclose the gap, and bonded to the first and second substrates, so as to form a hermetically sealed space surrounded with the first annular bonding member and the first and second substrates, comprises: a step of arranging the first annular bonding member between the first and second substrates; a step of arranging a second bonding member, between the first and second substrates, in a position different from a position in which the first annular bonding member is arranged; a step of elastically deforming at least one of the first and second substrates, so that a distance between the first and second substrates at a region in which the second bonding member is arranged is shorter than a distance between the first and second substrates at a region in which the first bonding member is arranged; a first bonding step of bonding the first bonding member to the first substrate, and bonding the first bonding member to the second substrate, to bond the first substrate to the second substrate through the first bonding member; and a second bonding step of bonding the second bonding member to the first substrate, and bonding the second bonding member to the second substrate, to bond the first substrate to the second substrate through the second bonding member, wherein at least one of the first and second bonding steps is performed under a state that the at least one of the first and second substrates is elastically deformed.

In the hermetic container of the invention, the container is in a state where at least one of the first and second substrates is elastically deformed and a compressing force acts continuously in the height direction of the first bonding member. Therefore, even if temperature distribution occurred in the hermetic container, the tractive force is difficult to act in the height direction of the first bonding member, even if glass frit is used as a first bonding member, the hermetic sealing can be easily maintained, and its reliability is improved. Since the first and second substrates are bonded not only by the first bonding member but also by the second bonding member, a bonding force can be improved more than that in the case of using only the first bonding member.

According to the image display apparatus of the invention, since the hermetic sealing can be certainly maintained and the bonding strength can be improved, the image display apparatus in which it is difficult to be damaged and its reliability is high can be obtained.

Further, according to the manufacturing method of the hermetic container of the invention and the manufacturing method of the image display apparatus of the invention, the hermetic container and the image display apparatus using the hermetic container as an envelope can be easily manufactured.

Further features of the present invention will become apparent from the following description of exemplary embodiments with reference to the attached drawings.

### BRIEF DESCRIPTION OF THE DRAWINGS

FIGS. 1A, 1B and 1C are schematic diagrams illustrating a first example of a hermetic container according to the invention, in which FIG. 1A is a partial cross sectional view, FIG. 1B is a partial plan view of a state where a second substrate is examined by fluoroscopy, and FIG. 1C is an enlarged cross sectional view around a light emitting portion.

FIGS. 2A, 2B, 2C, 2D, 2E and 2F are schematic diagrams illustrating an example of a procedure of a manufacturing method of the hermetic container according to the first example.

FIGS. 3A, 3B, 3C, 3D, 3E and 3F are schematic diagrams illustrating another example of the procedure of the manufacturing method of the hermetic container according to the first example.

FIGS. 4A and 4B are diagrams illustrating a second example of the hermetic container according to the invention, in which FIG. 4A is a partial cross sectional view and FIG. 4B is a partial plan view of a state where a second substrate is examined by fluoroscopy.

FIGS. 5A, 5B, 5C, 5D, 5E and 5F are schematic diagrams illustrating an example of a procedure of a manufacturing method of the hermetic container according to the second example.

FIGS. 6A and 6B are diagrams illustrating a third example of the hermetic container according to the invention, in which FIG. 6A is a partial cross sectional view and FIG. 6B is a partial plan view of a state where a second substrate is examined by fluoroscopy.

FIGS. 7A, 7B, 7C, 7D, 7E and 7F are schematic diagrams illustrating an example of a procedure of a manufacturing method of the hermetic container according to the third example.

FIGS. 8A and 8B are explanatory diagrams in the case of manufacturing an organic EL display apparatus using the hermetic container of the invention, in which FIG. 8A is a plan view and FIG. 8B is a cross sectional view.

### DESCRIPTION OF THE EMBODIMENTS

Preferred embodiments of the present invention will now be described in detail in accordance with the accompanying drawings.

A hermetically sealed container (hereinbelow, also referred to as a hermetic container) of the invention can be applied as an envelope of an image display apparatus such as FED, OLED, PDP, or the like having a device whose internal space needs to be hermetically sealed from an external atmosphere. A manufacturing method of the hermetic container of the invention can be applied as a manufacturing method of the envelope. Further, the hermetic container of the invention and its manufacturing method can be applied not only to an envelope of the image display apparatus and a manufacturing method of such an envelope but also widely to a hermetic container having bonding portions in which hermetic sealing is required and which are placed in peripheral edge portions of substrates such as glass or the like placed in opposition to each other. For example, the hermetic container of the invention and its manufacturing method can be applied vacuum heat insulation glass and its manufacturing method.

The invention will be described hereinbelow with reference to the drawings. In the following description, the well-known arts or prior arts in the relevant technical field can be applied to portions which are not particularly illustrated or disclosed. Items which will be described hereinbelow relate to an example of the embodiments of the invention to the end and the invention is not limited to them. Further, in the drawings which will be referred to in the following description, the same reference numerals indicate similar component elements.

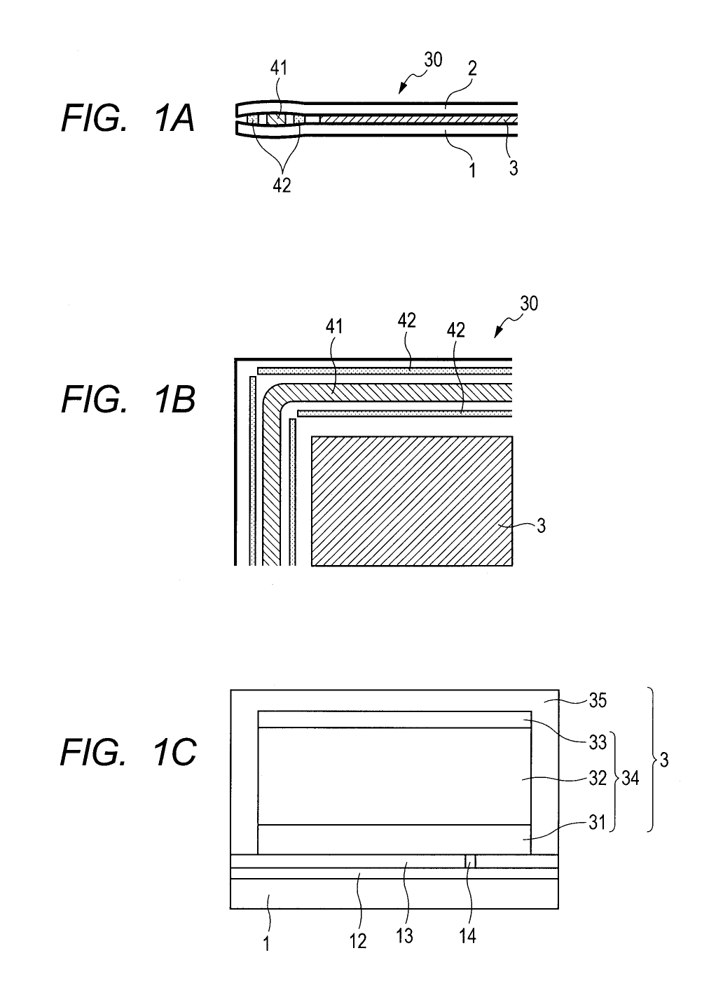

First, a first example of the hermetic container of the invention will be described with reference to FIGS. 1A to 1C.

A hermetic container 30 in the example constructs an envelope of an OLED. As illustrated in FIG. 1C, a TFT circuit 12, a planarized film 13, and a contact hole 14 are provided on a first substrate 1. A lower electrode 31, an organic EL layer 32, an upper electrode 33, and a protective layer 35 which construct a light emitting portion 3 are further provided on the planarized film 13. The first substrate 1 and a second substrate 2 are placed in opposition to each other to firm a gap therebetween in such a manner that a placing surface side of the first substrate 1 on which the light emitting portion 3 or the like is placed is set to the inside. A first bonding member 41 formed in a frame shape is provided between the first substrate 1 and the second substrate 2 so as to surround a gap between both of the substrates and to form a hermetically sealed space in which the light emitting portion 3 is enclosed. Since the hermetic container 30 in the example is applied and used as an envelope for the image display apparatus, the first bonding member 41 has an almost rectangular frame shape. However, a placing shape of the first bonding member 41 can be set to an arbitrary shape such as square, ellipse, or the like in accordance with use of the hermetic container 30 so long as it is a closed annular shape.

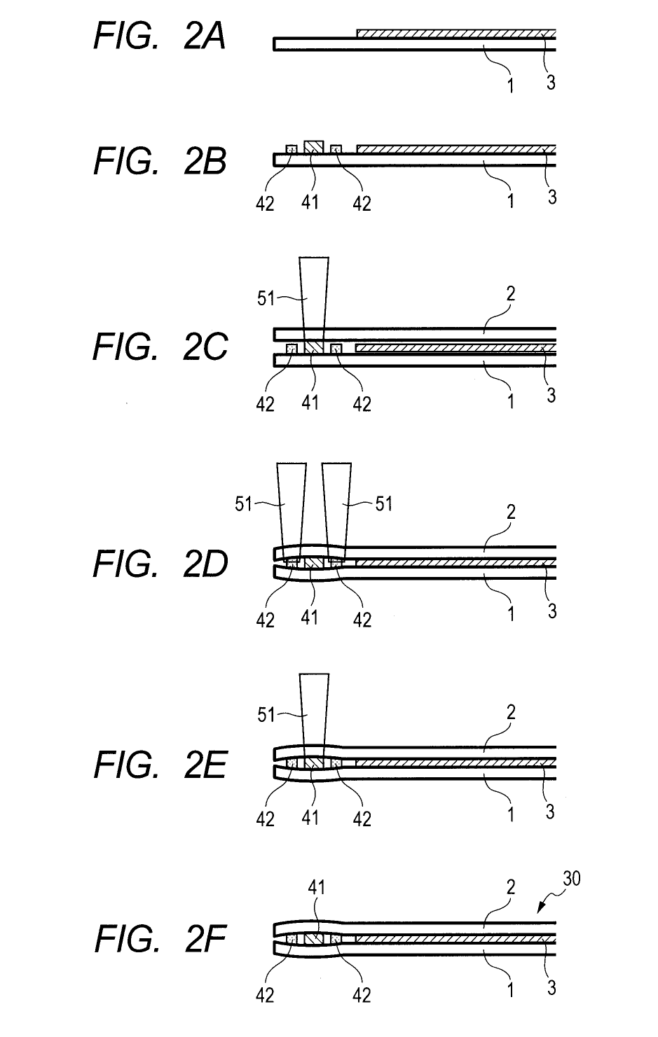

The first bonding member 41 is placed in a continuous annular shape and bonds the first substrate 1 and the second substrate 2, thereby forming a hermetically sealed space surrounded by the first and second substrates 1 and 2 and the first bonding member 41. As a first bonding member 41 which bonds the first substrate 1 and the second substrate 2 and applies hermetic sealing to the inside hermetically sealed space, glass frit in which high shielding performance is obtained is generally used. However, an inorganic adhesive or an organic adhesive can be also used in dependence on a pressure of the hermetically sealed space. In the case of using the glass frit, it is desirable that a viscosity has a negative temperature coefficient (temperature dependency), the glass frit is softened at a high temperature, and a softening point is lower than that of the first substrate 1 and the second substrate 2. In the case of using the glass frit as a first bonding member 41, either a bonding member obtained by adding a paste of the glass frit and baking it or a bonding member obtained by adding sheet frit may be used. It is desirable that the first bonding member 41 shows high absorbing performance to a wavelength of local heating light 51 (refer to FIGS. 2A to 2F), which will be described hereinafter.

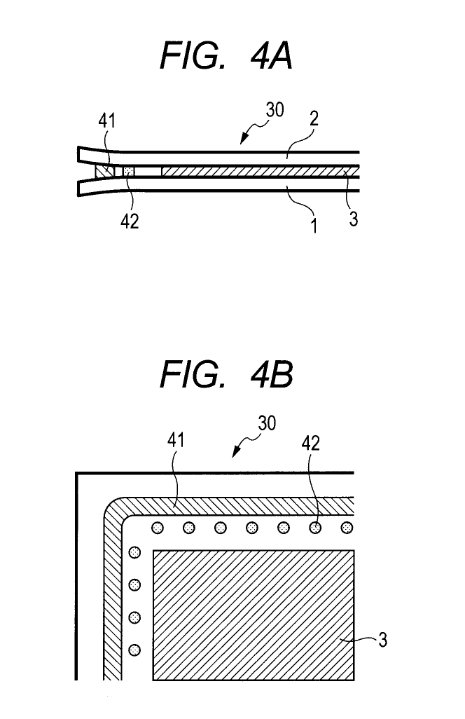

In the example, second bonding members 42 are placed on both sides of the inside and outside of the first bonding member 41, respectively. However, the second bonding member 42 can be also placed on only one of the inside and outside of the first bonding member 41. As a second bonding member 42, for example, besides the glass frit similar to the first bonding member 41, an inorganic adhesive, an organic adhesive, or the like can be used. Since a tractive force is applied to the second bonding member 42 in a height direction (direction in which the first substrate 1 and the second substrate 2 are placed in opposition to each other) as will be described hereinafter, a material whose toughness is higher than that of the first bonding member 41 is desirable. The second bonding member 42 does not need to be a continuous annular shape but can be also formed in a line segment shape, a broken line shape, or a dotted shape. In the case of using the inorganic adhesive or organic adhesive as a second bonding member 42, since a gas is liable to be generated under a high vacuum degree, it is desirable to provide the second bonding member 42 only outside of the first bonding member 41 so as not to exert an influence on the vacuum degree of the hermetically sealed space. It is desirable that bonding portions of the first and second bonding members 41 and 42 to at least one of the first and second substrate are separated from each other, in order to form a compressing force exerted selectively on the first bonding member 41. It is more desirable that, as shown in FIGS. 1A and 4B, the bonding portions of the first and second bonding members 41 and 42 to both of the first and second substrates 1 and 2 are separated from each other, since the compressing force exerted selectively on the first bonding member 41 can be formed more easily.

It is desirable to provide the second bonding members 42 in parallel with the first bonding member 41 in order to raise the bonding strength of the first and second substrates 1 and 2. If the air is sealed between the second bonding member 42 and the first bonding member 41, there is a case where a load is applied to the bonding portion due to an expansion of the sealed air. To prevent such a situation, it is desirable that the second bonding member 42 on the inner peripheral side has a discontinuous portion for communicating the space between the first bonding member 41 and the second bonding member 42 with the hermetically sealed space inside of the second bonding member 42. It is desirable that the second bonding member 42 on the outer peripheral side has a discontinuous portion for communicating the space between the first bonding member 41 and the second bonding member 42 with an external space. In the example, the discontinuous portion is formed at a position corresponding to a corner portion of the first bonding member 41 formed in a rectangular shape. The discontinuous portion can be also formed by providing the second bonding members 41 in a broken line shape or a dotted shape. The second bonding members 42 are also sandwiched between the first and second substrates 1 and 2, thereby bonding them.

A height of the first bonding member 41 (interval in the direction where the first substrate 1 and the second substrate 2 are placed in opposition to each other) is larger than a height of the second bonding member 42. Therefore, the first and second substrates 1 and 2 are elastically deformed in a convex shape in which a center in a width direction of the first bonding member 41 is set to a vertex. A compressing force is applied in the height direction of the first bonding member 41 due to the deformation of the first and second substrates 1 and 2. The tractive force acts in the height direction of the second bonding members 42. Although both of the first and second substrates 1 and 2 are elastically deformed in the example, only one of them may be elastically deformed.

A height of a center portion in the width direction of the first bonding member 41 is larger than a height of an edge portion in the width direction of the first bonding member 41 on the second bonding member side. That is, an upper surface and a lower surface of the first bonding member 41 are in a mountain shape in the width direction, respectively. Therefore, stress concentration in the elastically deforming portion of each of the first and second substrates 1 and 2 is difficult to occur, thereby making it easy to prevent a damage of the elastically deforming portion.

Since the first and second substrates 1 and 2 are bonded not only by the first bonding member 41 but also by the second bonding members 42, the bonding strength is improved more than that in the case of bonding them only by the single first bonding member 41. Therefore, a mechanical strength of the hermetic container 30 increases and it is possible to prevent the hermetic container 30 from being damaged by a mechanical disturbance (shock, vibration, distortion). Particularly, if the second bonding members 42 are provided on both sides of the first bonding member 41 as mentioned in the example, the larger bonding strength of the first and second substrates 1 and 2 can be easily obtained. Since the compressing force is continuously applied in the height direction of the first bonding member 41, the tractive force is difficult to act in the height direction of the first bonding member 41. Even if the first bonding member 41 is formed from the glass frit, the hermetic sealing can be easily maintained and the reliability can be raised.

Subsequently, a manufacturing method of the hermetic container 30 will be described with respect to the case of using the glass frit as a first bonding member 41 and second bonding members 42 as an example.

First, a manufacturing method illustrated in FIGS. 2A to 2F will be described. The first bonding member 41 is placed in an annular shape so as to surround the light emitting portion 3 of the first substrate 1. The first bonding member 41 can be formed by printing and baking. However, it is not always necessary to print bake the first bonding member 41 onto the first substrate 1 but the first bonding member 41 may be print baked onto the second substrate 2. The first bonding member 41 can be also placed by arranging the sheet frit between the first and second substrates 1 and 2 instead of forming it by the printing and baking.

The second bonding members 42 are placed inside and outside of the first bonding member 41 which will be placed or has been placed in a step of placing the first bonding member 41. Although the second bonding members 42 were placed inside and outside of the first bonding member in the example, the second bonding members 42 can be also placed only inside or outside of the first bonding member 41 as will be described hereinafter. The second bonding member 42 may be formed on any one of the first and second substrates 1 and 2. In the case of forming the second bonding members 42 onto the first substrate 1 on which the first bonding member 41 has been placed, it is sufficient to form the second bonding members 42 in parallel with the first bonding member 41. In the case of forming the second bonding members 42 onto the first substrate 1 or the second substrate 2 before the first bonding member 41 is placed, it is sufficient to form the second bonding members 42 at the positions serving as an inside and an outside of the first bonding member 41 when the first and second substrates 1 and 2 are placed in opposition to each other. Although the shape and positions of the second bonding members 42 are not particularly limited, they are desirably placed at the positions which are parallel with the first bonding member 41 and have a discontinuous portion.

The second bonding members 42 may be formed by printing and baking a material similar to that of the first bonding member 41. In the following description, it is assumed that the second bonding members 42 were formed by printing and baking the material similar to that of the first bonding member 41. In the example, the second bonding members 42 are formed lower than the first bonding member 41.

The step of placing the second bonding members 42 may be set to any one of the timing before the step of placing the first bonding member 41, the simultaneous timing, and the timing after it. In the case of forming the second bonding members 42 and the first bonding member from the same glass frit, they can be simultaneously formed and placed by printing and baking them together.

After the first bonding member 41 and the second bonding members 42 were formed and placed, the first substrate 1 and the second substrate 2 are adhered through the first annular bonding member 41. In the example, since the first bonding member 41 is formed higher than the second bonding members 42, the second bonding members 42 are not come into contact with both of the first substrate 1 and the second substrate 2. On the other hand, the first bonding member 41 is come into contact with both of the first and second substrates 1 and 2.

Subsequently, the local heating light 51 is scanned along the length direction of the first bonding member 41 sandwiched between the first and second substrates 1 and 2. A semiconductor laser is suitable as a light source. A semiconductor laser for working having a wavelength in a band of infrared rays is desirable from viewpoints of performance of locally heating the first bonding member 41, permeability of the second substrate 2 serving as an irradiating side of the local heating light 51, and the like. Although a state where the local heating light 51 is irradiated from the side of the second substrate 2 is illustrated in the drawing, the local heating light 51 can be also irradiated from the side of the first substrate 1.

The first bonding member 41 is sequentially heated along the length direction by the irradiation of the local heating light 51, is adhered to the second substrate 2, and thereafter, is cooled to the softening point or less. Thus, the first substrate 1 and the second substrate 2 are bonded through the first bonding member 41. When the whole first bonding member 41 is sealed and the bonding step is finished, the hermetic container 30 in which the internal space surrounded by the first bonding member 41 is hermetically sealed is completed.

Subsequently, one or both of the first substrate 1 and the second substrate 2 is/are pressed, at least one of the first substrate 1 and the second substrate 2 is elastically deformed, and the second bonding members 42 are sandwiched with a pressure by the first substrate 1 and the second substrate 2. After the second bonding members 42 were fused by the local heating in this state, the second bonding members 42 are hardened, and the first substrate 1 and the second substrate 2 are also bonded by the second bonding members 42. If both of the first substrate 1 and the second substrate 2 are pressed instead of pressing only one of them, the second bonding members 42 can be more easily come into pressure contact with both of the first substrate 1 and the second substrate 2. The fusion of the second bonding members 42 can be performed by scanning the local heating light 51 along the length direction of the second bonding members 42 in a manner similar to the first bonding member 41. The second bonding members 42 are sequentially heated along the length direction by the irradiation of the local heating light 51, are fused, and thereafter, are cooled to the softening point or less. Thus, the first substrate 1 and the second substrate 2 are also bonded by the second bonding members 42. All of the second bonding members 42 are bonded and the bonding step of the first substrate 1 and the second substrate 2 is finished.

In the case of using the glass frit, the bonding by the first bonding member 41 and the second bonding members 42 is performed by heating and fusing them. However, in the case of using the inorganic adhesive, organic adhesive, or the like, the first substrate 1 and the second substrate 2 can be bonded by holding the first and second substrates 1 and 2 in a bonding state and hardening them as they are instead of the heating fusion. If the inorganic adhesive or the organic adhesive is an adhesive of the ultraviolet hardening type, the first and second substrates 1 and 2 can be hardened and bonded by irradiating ultraviolet rays under a pressure sandwiching state.

Although the manufacturing step of the hermetic container 30 may be finished in this state, it is desirable that the first bonding member 41 is further heated again by the local heating in this state and is softened while maintaining a state where the compressing force has been applied in the height direction of the first bonding member 41. By heating it again as mentioned above, the height of the edge portion in the width direction of the first bonding member 41 on the side of the second bonding members 42 is pressed and contracted and the height of the center portion in the width direction of the first bonding member can be set to be higher than the height of the edge portion in the width direction of the first bonding member 41 on the side of the second bonding members 42. Thus, the stress concentration on the elastically deforming portions of the first substrate 1 and the second substrate 2 can be easily prevented. The foregoing re-heating may be performed, for example, either by the local heating in which the first bonding member 41 is sequentially scanned in the length direction by the local heating light 51 or by the whole heating using a heating furnace.

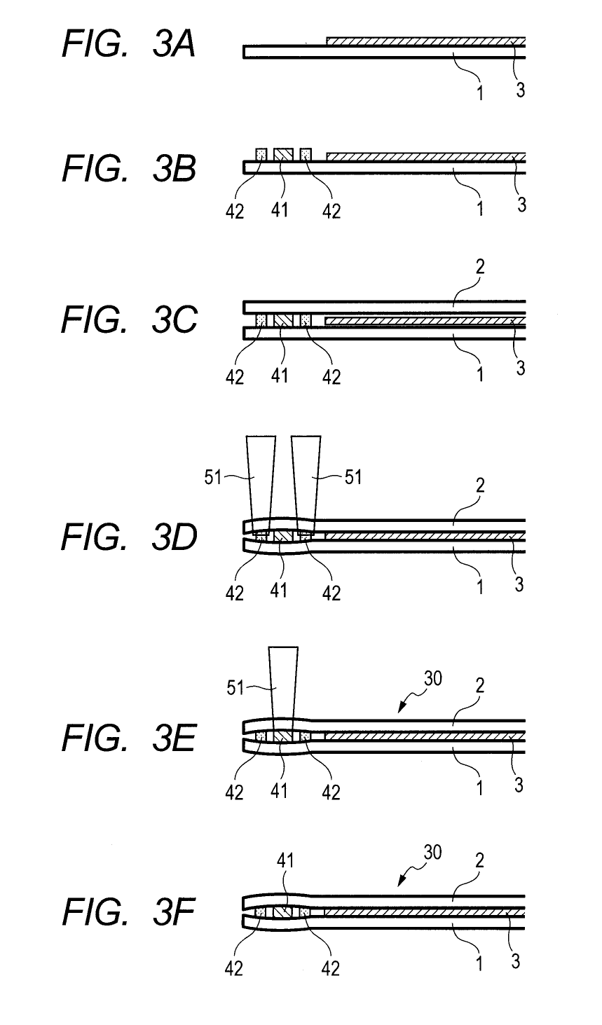

The hermetic container 30 according to the first example illustrated in FIGS. 1A to 1C can be also manufactured by a procedure illustrated in FIGS. 3A to 3F. A layout and creation of the first bonding member 41 and the second bonding members 42 are similar to those in the method described in FIGS. 2A to 2F. However, in this example, the height of the second bonding member 42 may be lower or higher than that of the first bonding member 41.

First, a case where the height of the second bonding member 42 is lower than that of the first bonding member 41 will be described. In this case, after the first substrate 1 and the second substrate 2 were placed in opposition to each other, one or both of the first substrate 1 and the second substrate 2 is/are pressed, at least one of the first substrate 1 and the second substrate 2 is elastically deformed, and the second bonding members 42 are sandwiched with a pressure by the first and second substrates 1 and 2. In this pressure sandwiching state, the second bonding members 42 are fused, for example, by the local heating in which the second bonding members 42 are sequentially scanned in the length direction by the local heating light 51 and, thereafter, is hardened, thereby bonding the first substrate 1 and the second substrate 2 by the second bonding members 42. Thus, the height of the first bonding member 41 is higher than that of the second bonding member 42, at least one of the first substrate 1 and the second substrate 2 is elastically deformed, the first and second substrates 1 and 2 are bonded by the second bonding members 42, and a state where the compressing force has been applied in the height direction of the first bonding member 41 is constructed. After that, by fusing the first bonding member 41 by the local heating and, thereafter, hardening it, the first and second substrates 1 and 2 are bonded by the first bonding member 41 while maintaining the state where the compressing force has been applied in the height direction of the first bonding member 41. By the above steps, the hermetic container 30 illustrated in FIGS. 1A to 1C can be also manufactured. In this case, the bonding of the first and second substrates 1 and 2 by the first bonding member 41 is performed in the state where the compressing force has been applied to the first bonding member 41. Therefore, upon bonding of the first and second substrates 1 and 2 by the first bonding member 41, the height of the edge portion in the width direction of the first bonding member 41 on the side of the second bonding member 42 is pressed and contracted. That is, the height of the center portion in the width direction of the first bonding member 41 can be set to be higher than the height of the edge portion in the width direction of the first bonding member 41 on the side of the second bonding member 42 without heating again.

Subsequently, a case where the height of the second bonding member 42 is equal to or higher than the height of the first bonding member 41 will be described. In this case, after the first substrate 1 and the second substrate 2 were placed in opposition to each other, one or both of the first substrate 1 and the second substrate 2 is/are pressed, thereby obtaining a state where the second bonding members 42 have been sandwiched with a pressure by the first and second substrates 1 and 2. At least one of the first substrate 1 and the second substrate 2 is elastically deformed and the second bonding members 42 are pressed and contracted until the height of the second bonding member 42 is lower than that of the first bonding member 41. If the second bonding members 42 are formed from the glass frit, the second bonding members are fused at this time of sandwiching with the pressure. After the second bonding members 42 were pressed and contracted, the second bonding members 42 are hardened and the first substrate 1 and the second substrate 2 are bonded by the second bonding members 42. Thus, the height of the first bonding member 41 is higher than that of the second bonding member 42, at least one of the first and second substrates 1 and 2 is elastically deformed, the first substrate 1 and the second substrate 2 are bonded by the second bonding members 42, and the state where the compressing force has been applied in the height direction of the first bonding member 41 is constructed. After that, by fusing the first bonding member 41 by the local heating and, thereafter, hardening it, the first substrate 1 and the second substrate 2 are bonded by the first bonding member 41 while maintaining the state where the compressing force has been applied in the height direction of the first bonding member 41. By the foregoing steps, the hermetic container 30 in FIGS. 1A to 1C can be manufactured. Also in this case, the height of the center portion in the width direction of the first bonding member 41 can be set to be higher than the height of the edge portion in the width direction of the first bonding member 41 on the side of the second bonding member 42 without heating again.

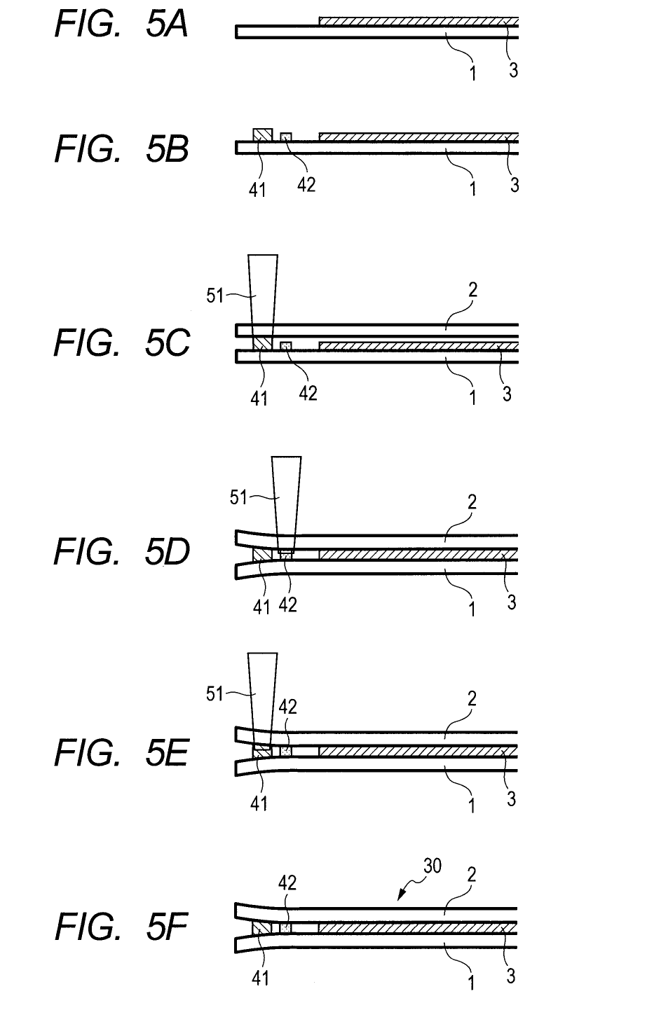

In the hermetic container 30 according to the second example illustrated in FIGS. 4A and 4B, the second bonding members 42 are formed in series in a dotted shape and, moreover, are provided only inside of the first bonding member 41. As illustrated in FIGS. 5A to 5F, a manufacturing procedure of the hermetic container 30 is fundamentally the same as the procedure of FIGS. 2A to 2F.

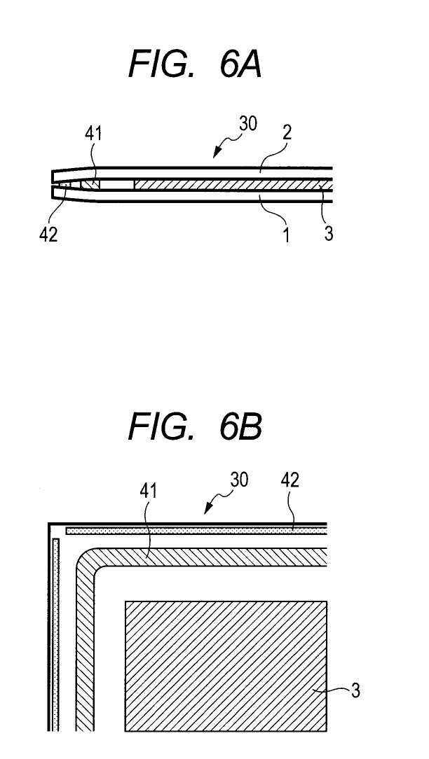

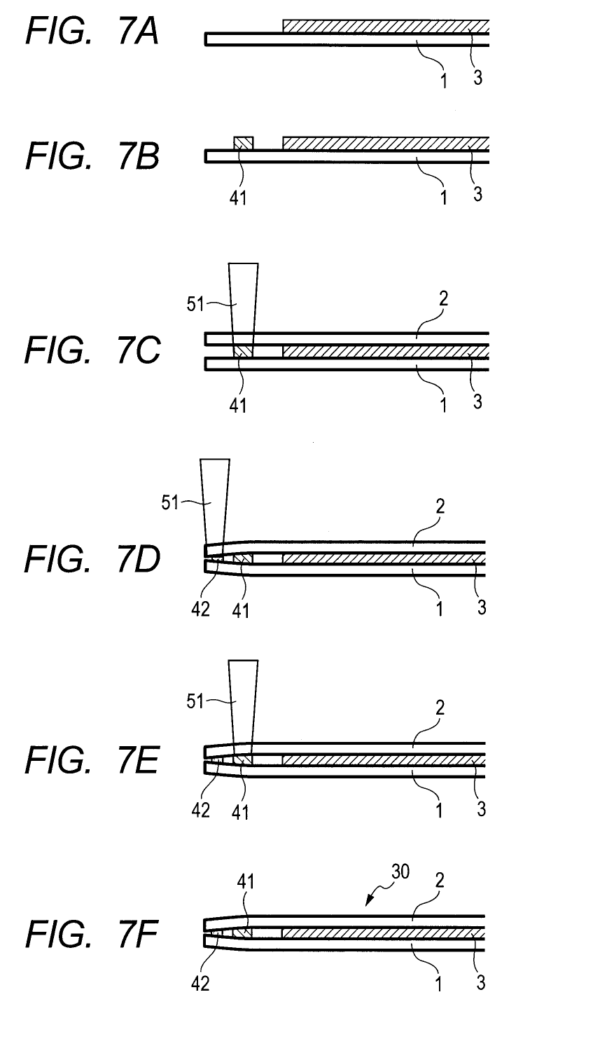

In the hermetic container 30 according to the third example illustrated in FIGS. 6A and 6B, the second bonding members 42 are formed in a line segment shape and, moreover, are provided only outside of the first bonding member 41. Although the hermetic container 30 can be manufactured in a manner similar to the procedure of FIGS. 2A to 2F, as illustrated in FIGS. 7A to 7F, it can be also manufactured by placing the second bonding members 42 after that. That is, after only the first bonding member 41 had been placed and the first substrate 1 and the second substrate 2 were bonded by the first bonding member 41, the second bonding members 42 may be injected into an outer peripheral edge portion of a gap between the bonded first and second substrates 1 and 2. After the second bonding members 42 were injected, one or both of the bonded first and second substrates 1 and 2 is/are pressed, one or both of the bonded first and second substrates 1 and 2 is/are elastically deformed, and the second bonding members 42 are sandwiched with a pressure by the first substrate 1 and the second substrate 2. By hardening the second bonding members 42 in this state, the first and second substrates 1 and 2 are bonded by the second bonding members 42. Thus, the height of the first bonding member 41 is higher than that of the second bonding member 42, at least one of the first and second substrates 1 and 2 is elastically deformed, the first and second substrates 1 and 2 are bonded by the first bonding member 41 and the second bonding members 42, and a state where the compressing force has been applied in the height direction of the first bonding member 41 is constructed.

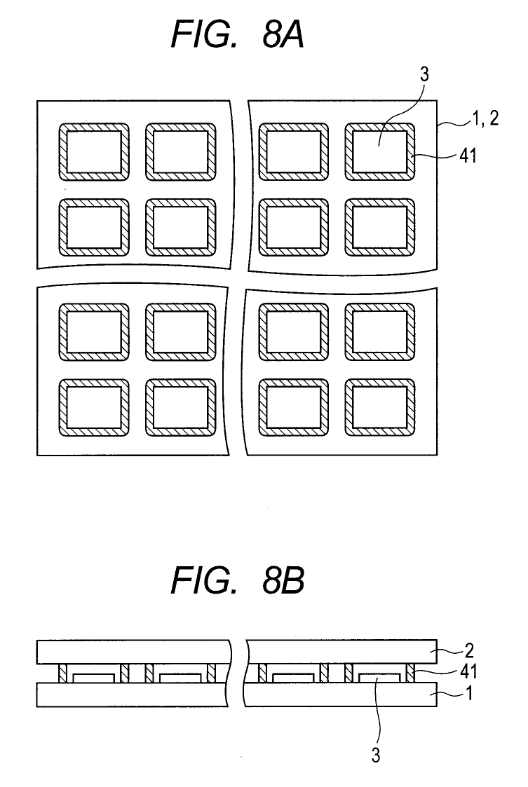

In the case of manufacturing an OLED using the hermetic container of the invention as an envelope, as illustrated in FIGS. 8A and 8B, the first large substrate 1 in which a plurality of light emitting portions 3 or the like are formed and the second substrate 2 are placed in opposition to each other and are bonded by the first bonding member 41 and the second bonding member 42 arranged around each light emitting portion 3. After that, a plurality of OLEDs can be also manufactured in a lump by cutting the bonded substrates on a unit basis around the light emitting portion 3 as a center. The bonded substrates can be also cut after they were bonded by one of the first bonding member 41 and the second bonding member 42. The second bonding member 42 is not illustrated in FIGS. 8A and 8B. FIGS. 1A to 7F are diagrams illustrating the edge portion of the large substrate (mother glass) as illustrated in FIGS. 8A and 8B in order to make a description easy.

### Example 1

In this Example, the hermetic container 30 which has been described in FIGS. 1A to 1C and constructs the envelope of the OLED is manufactured by the procedure of FIGS. 2A to 2F. While describing the manufacturing method of the hermetic container 30, the structure of the hermetic container 30 will be also described hereinbelow.

First, the first substrate 1 and the second substrate 2 are prepared as illustrated in FIGS. 1A to 1C and 2A. The first substrate 1 is a glass plate having a thickness of 0.5 mm. The TFT circuit 12, planarized film 13, and contact hole 14 are provided on the first substrate 1. The lower electrode 31, organic EL layer 32, upper electrode 33, and protective layer 35 which construct the light emitting portion 3 are further provided on the planarized film 13.

Subsequently, as illustrated in FIG. 2B, the first bonding member 41 is screen printed in an annular shape so as to surround the light emitting portion 3. The second bonding members 42 are respectively placed on both sides of the inside and outside of the first bonding member 41 placed in the annular shape. The second bonding members are made of a material similar to that of the first bonding member 41 and are formed by the screen printing. The second bonding members 42 are placed in a straight line segment shape in parallel with the first bonding member 41. The material constructing the first bonding member 41 and the second bonding members 42 is the lead-free glass frit of a Bi system having a transition point of 357° C. and a softening point of 420° C. as a base material. A paste in which an organic substance is dispersed and mixed is used as a binder. After the screen printing, the second bonding members 42 are dried at 120° C. together with the first substrate 1. They are heated and baked at 460° C. to burn out the organic substance, thereby forming the first bonding member 41 and the second bonding members 42. In this glass frit, a viscosity has a negative temperature coefficient (temperature dependency).

The first bonding member 41 obtained after the baking has dimensions of a width of 1 mm and a height of 100 μm and is formed in an annular shape so as to surround the light emitting portion 3. Each of the second bonding members 42 obtained after the baking has dimensions of a width of 1 mm and a height of 80 μm and they are formed inside and outside of the first bonding member 41 placed in the annular shape in parallel with the first bonding member 41 at a position away from the first bonding member 41 by 2 mm. The second bonding members 42 are provided with a discontinuous portion at the position corresponding to a corner portion of the first bonding member 41.

Subsequently, as illustrated in FIG. 2C, the first substrate 1 and the second substrate 2 are placed in opposition to each other through the first annular bonding member 41. Since the first bonding member 41 is formed higher than the second bonding members 42, the second bonding members 42 are not come into contact with both of the first substrate 1 and the second substrate 2.

Subsequently, the local heating light 51 is scanned along the length direction of the first bonding member 41 sandwiched between the first and second substrates 1 and 2. The semiconductor laser for working having the wavelength in the band of infrared rays is used as a light source from the viewpoints of performance of locally heating the first bonding member 41, permeability of the glass substrate, and the like. The first bonding member 41 is sandwiched between the first and second substrates 1 and 2 in order to desirably perform the bonding by the local heating light 51.

By irradiating the laser beam serving as local heating light 51 while scanning it along the first bonding member 41, the first bonding member 41 is sequentially heated along the length direction, is fused, and thereafter, is cooled to the softening point or less. Thus, the first substrate 1 and the second substrate 2 are locally bonded. By the bonding by the local heating light 51, the height of the first bonding member 41 is set to 90 μm. In this manner, the first substrate 1 and the second substrate 2 are bonded by the first bonding member 41, thereby forming the hermetic container 30 having the sealed internal space.

As for the local heating light 51, two semiconductor laser apparatuses for working (not shown) are prepared and placed so that irradiating spots of the first laser light source and the second laser light source are aligned on a straight line. The first laser light source emits a laser beam having a wavelength of 980 nm, a laser power of about 250 W, and an effective diameter of 2 mm and scans the laser beam at a speed of 1000 mm/sec. The second laser light source is placed so as to be delayed by 0.5 second from the laser beam emitted from first laser light source, that is, at a position on the rear side in the scanning direction from the first laser light source by a distance of 50 mm as an irradiating spot. Such an interval is also maintained for a scanning period of time. The laser beam emitted from the second laser light source has the wavelength of 980 nm, the laser power of about 250 W, and the effective diameter of 2 mm.

Subsequently, as illustrated in FIG. 2D, an external force is applied so as to sandwich the first substrate 1 and the second substrate 2 and a pressure is applied to the second bonding members 42 through the first substrate 1 and the second substrate 2. In this state, the local heating light 51 is scanned along the length direction of the second bonding members 42 sandwiched between the first and second substrates 1 and 2. The light sources and irradiating conditions are set to substantially the same as those upon bonding of the first bonding member 41. The height of the second bonding member 42 is set to 70 μm by the bonding by the local heating light 51.

According to the hermetic container 30 manufactured as mentioned above, since the height of the first bonding member 41 is higher than that of the second bonding member 42, the first and second substrates 1 and 2 are deformed in the convex shape around the first bonding member 41 as a center. By the deformation of the first and second substrates 1 and 2, the compressing force of about 10 MPa can be applied in the height direction of the first bonding member 41.

As illustrated in FIG. 2E, by heating again the first bonding member 41 by the local heating light 51 and softening it, a height of both edge portions in the width direction of the first bonding member 41 can be set to be lower than a height of a center portion in the width direction. Thus, the first and second substrates 1 and 2 can be gently deformed and a state where such a situation that large stress concentration occurs in the elastically bending portion can be easily prevented can be obtained. As conditions of the local heating light 51 at the time of the re-heating, the light source emits the laser beam having the wavelength of 980 nm, the laser power of about 250 W, and the effective diameter of 2 mm and scans the laser beam at the speed of 1000 mm/sec.

After the first substrate 1 and the second substrate 2 were bonded as mentioned above, the first and second substrates 1 and 2 are cut by an ordinary method, thereby forming (m×n) hermetic containers 30 (envelopes). By mounting a driving circuit and the like, the OLED having the hermetic containers 30 as envelopes is completed. When the completed OLED is made operative, it has been confirmed that an image can be stably displayed for a long time and such stable hermetic sealing that the hermetic containers can be applied to the OLED is assured.

### Example 2

Example 2 will be described with reference to FIGS. 3A to 3F. In a manner similar to the Example 1, the first substrate 1 and the second substrate 2 are prepared and the first bonding member 41 and the second bonding members 42 are placed. At this time, the second bonding members 42 are formed so as to have a height similar to that of the first bonding member 41.

Subsequently, as illustrated in FIGS. 3C and 3D, the local heating light 51 is irradiated to the second bonding members 42, thereby bonding the first and second substrates 1 and 2. At this time, a pressure is applied to the second bonding members 42 through the first and second substrates 1 and 2. The second bonding members 42 are thinner than the first bonding member 41 by the local heating light 51 and the pressure.

Subsequently, as illustrated in FIG. 3E, by irradiating the local heating light 51 to the first bonding member 41, the first substrate 1 and the second substrate 2 are bonded. Since the first bonding member 41 has the annular shape, the hermetic container 30 is formed by the bonding of the first bonding member 41. At this time, in the first bonding member 41 just after the bonding, the height of the center portion in the width direction is higher than that of the edge portion on the side of the second bonding members 42, so that the elastically deforming portions of the first substrate 1 and the second substrate 2 can be gently deformed.

After the first substrate 1 and the second substrate 2 were bonded as mentioned above, the first substrate 1 and the second substrate 2 are cut by the ordinary method, thereby forming (m×n) hermetic containers 30 (envelopes). By mounting the driving circuit and the like, the OLED having the hermetic containers 30 is completed. When the completed OLED is made operative, it has been confirmed that an image can be stably displayed for a long time and such stable hermetic sealing that the hermetic containers can be applied to the OLED is assured.

### Example 3

Example 3 will be described with reference to FIGS. 4A to 5F.

In a manner similar to the Example 1, the first substrate 1 and the second substrate 2 are prepared.

Subsequently, the second bonding members 42 are placed inside of the first bonding member 41 placed in the annular shape. The first bonding member 41 and the second bonding members 42 are formed from the glass frit in a manner similar to the Example 1 and are formed by the screen printing. The second bonding members 42 are placed in a continuous dotted shape in parallel with the first bonding member 41.

The first bonding member 41 is bonded by using the local heating light 51 in a manner similar to the Example 1. After that, the first substrate 1 and the second substrate 2 are bent so as to sandwich the second bonding members 42 with a pressure, thereby bonding the first and second substrates 1 and 2 by using the local heating light 51.

Further, as illustrated in FIG. 5E, the first bonding member 41 is heated again by the local heating light 51 so as to be softened. Thus, the height of the center portion in the width direction of the first bonding member 41 is higher than that of the edge portion of the first bonding member 41 on the side of the second bonding members 42 and the first substrate 1 and the second substrate 2 can be gently elastically deformed.

After the first substrate 1 and the second substrate 2 were bonded as mentioned above, the first substrate 1 and the second substrate 2 are cut by the ordinary method, thereby forming (m×n) hermetic containers 30 (envelopes). By mounting the driving circuit and the like, the OLED having the hermetic containers 30 as envelopes is completed. When the completed OLED is made operative, it has been confirmed that an image can be stably displayed for a long time and such stable hermetic sealing that the hermetic containers can be applied to the OLED is assured.

### Example 4

Example 4 will be described with reference to FIGS. 6A to 7F.

In a manner similar to the Example 1, the first substrate 1 and the second substrate 2 are prepared.

Only the first bonding member 41 is placed in a manner similar to the Example 1, the local heating light 51 is irradiated, and the first substrate 1 and the second substrate 2 are bonded. After that, the first substrate 1 and the second substrate 2 are cut by the ordinary method, thereby forming (m×n) hermetic containers 30 in which the first and second substrates 1 and 2 were bonded only by the first bonding member 41.

Subsequently, a light hardening type adhesive is injected as a second bonding member 42 by using a dispenser into the gap between the first substrate 1 and the second substrate 2 which are opened to the peripheral edge portion of the obtained hermetic container 30. While deforming the first substrate 1 and the second substrate 2 so as to crush their edge portions, UV light 52 is irradiated to the second bonding member 42 so as to be softened.

Further, as illustrated in FIG. 7E, the first bonding member 41 is heated again by the local heating light 51 so as to be softened. Thus, the height of the first bonding member 41, that is, a thickness of the center portion in the width direction of the first bonding member is larger than the height of the edge portion of the first bonding member 41 outside in the width direction thereof (on the side of the second bonding members 42), and the elastically deforming portions of the first substrate 1 and the second substrate 2 can be gently deformed.

The hermetic containers 30 (envelopes) are manufactured as mentioned above and, further, the driving circuit and the like are mounted by the ordinary method, thereby completing the OLED having the hermetic containers 30 as envelopes. When the completed OLED is made operative, it has been confirmed that an image can be stably displayed for a long time and such stable hermetic sealing that the hermetic containers can be applied to the OLED is assured

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-073901, filed Mar. 20, 2011, which is hereby incorporated by reference herein in its entirety.

What is claimed is:

1. A hermetic container comprising:
first and second substrates placed in opposition to each other to firm a gap between the first and second substrates;
a first annular bonding member placed to enclose at least part of the gap between the first and second substrates, and bonded to the first and second substrates, so as to form a hermetically sealed space surrounded with the first annular bonding member and the first and second substrates; and
a second bonding member placed, between the first and second substrates, in a region different from a region in which the first annular bonding member is placed, and bonded to the first and second substrates, wherein
the second bonding member has a height smaller than a height of the first annular bonding member, at least one of the first and second substrates is elastically deformed, from a region bonded to the first bonding member to a region bonded to the second bonding member, so as to form a compressing force in a direction of the height of the first bonding member.

2. The hermetic container according to claim 1, wherein
at least one of the first and second substrates is bonded to the first and second bonding members such that the region bonded to the first bonding member is spaced from the region bonded to the second bonding member.

3. The hermetic container according to claim 1, wherein
the first bonding member is formed from glass frit and the second bonding member is formed from glass frit, inorganic adhesive, or organic adhesive.

4. The hermetic container according to claim 1, wherein
a height of the first bonding member at a center in a width direction of the first bonding member is larger than a height of the second bonding member at an end in the width direction of the first bonding member.

5. The hermetic container according to claim 1, wherein
the second bonding member has a discontinuous portion.

6. An image display apparatus comprising
a hermetic container according to claim 1, as an envelope.

7. A method for manufacturing a hermetic container, wherein the hermetic container comprises:
first and second substrates placed in opposition to each other to firm a gap between the first and second substrates;
a first annular bonding member placed to enclose the gap, and bonded to the first and second substrates, so as to form a hermetically sealed space surrounded with the first annular bonding member and the first and second substrates, wherein the method comprises:
a step of arranging the first annular bonding member between the first and second substrates;
a step of arranging a second bonding member, between the first and second substrates, in a position different from a position in which the first annular bonding member is arranged;
a step of elastically deforming at least one of the first and second substrates, so that a distance between the first and second substrates at a region in which the second bonding member is arranged is shorter than a distance between the first and second substrates at a region in which the first bonding member is arranged;
a first bonding step of bonding the first bonding member to the first substrate, and bonding the first bonding member to the second substrate, to bond the first substrate to the second substrate through the first bonding member; and
a second bonding step of bonding the second bonding member to the first substrate, and bonding the second bonding member to the second substrate, to bond the first substrate to the second substrate through the second bonding member, wherein
at least one of the first and second bonding steps is performed under a state that the at least one of the first and second substrates is elastically deformed.

8. The method according to claim 7, wherein
the first bonding member is formed from glass frit and the second bonding member is formed from glass frit, inorganic adhesive, or organic adhesive, and,
after bonding to the second bonding member, the first bonding member is heated to soften the first bonding member while keeping the at least one of the first and second substrates at the elastically deformed state.

9. The method according to claim 7, wherein
the first bonding member is formed from glass frit and the second bonding member is formed from glass frit, inorganic adhesive, or organic adhesive.

10. The method according to claim 7, wherein,
in step of arranging the second bonding member, the second bonding member having a discontinuous portion is arranged.

11. A method of manufacturing an image display apparatus comprising
a method for manufacturing a hermetic container according to claim 7, as a method for manufacturing an envelope of the image display apparatus.
